(19) United States
(12) Patent Application Publication
(10) Pub. No.: US 2015/0340080 A1
(43) Pub. Date: Nov. 26, 2015

(54) Refreshing Dynamic Memory

(71) Applicant: Jean Baptiste Maurice Queru, Foster City, CA (US)

(72) Inventor: Jean Baptiste Maurice Queru, Foster City, CA (US)

(21) Appl. No.: 13/438,963

(22) Filed: Apr. 4, 2012

(51) Int. Cl. G11C 7/00

(52) U.S. Cl. CPC G11C 11/40622

(57) ABSTRACT

A method of refreshing dynamic memory includes associating, for each refreshable memory element of a dynamic random access memory device, an indicator with the refreshable memory element. The method also includes detecting a predetermined data value being written to a memory location associated with a first refreshable memory element, and setting the indicator associated with the first refreshable memory element to a first value. The method further includes refreshing only the refreshable memory elements of the dynamic random access memory device whose associated indicators have values different from the first value, wherein refreshing does not comprise refreshing the first refreshable memory element.

### TECHNICAL FIELD

This document discusses refreshing dynamic memory.

### BACKGROUND

Dynamic random access memory (DRAM) devices are semiconductor memory devices that are frequently used to store digital information for computing applications. Unlike static random access memory (SRAM) devices that include four-to-ten transistors-per-bit of memory to maintain a latched logic level, DRAM devices typically include one transistor and one storage capacitor per memory bit, with the capacitor storing a charge that indicates the logic level. While this reduced hardware configuration permits DRAMs to be manufactured inexpensively and results in a lower-cost memory component, DRAM's reliance on capacitors for charge storage imparts maintenance overhead to the system.

For example, because of a charge leakage phenomenon that can cause degradation of passively stored charges over time in semiconductor devices, the values stored by the DRAM capacitors are traditionally “refreshed” periodically. Refreshing a stored DRAM value typically involves first reading the value from a memory location and then writing the value back to the memory location. Modern DRAM devices can be refreshed every 32 milliseconds (ms) or 64 ms to maintain data integrity, and this maintenance overhead can consume significant amounts of power in power-conscious, battery-powered applications. Traditionally, all DRAM memory locations are periodically refreshed in this manner so that the values stored by the memory locations do not become indeterminate, and thus unreliable, because of the charge leakage phenomenon. The power consumption associated with periodically refreshing all dynamic memory locations may result in reduced battery life in battery-powered implementations.

### SUMMARY

This document describes devices, systems and methods that may be used to conserve power and extend battery life for computing devices or systems that use dynamic memory.

In a first general aspect, a method of refreshing dynamic memory includes associating, for each refreshable memory element of a dynamic random access memory device, an indicator with the refreshable memory element. The method also includes detecting a predetermined data value being written to a memory location associated with a first refreshable memory element, and setting the indicator associated with the first refreshable memory element to a first value. The method further includes refreshing only the refreshable memory elements of the dynamic random access memory device whose associated indicators have values different from the first value, wherein refreshing does not comprise refreshing the first refreshable memory element.

In various implementations, the predetermined data value may be zero. An operating system or an application may initiate the writing of the predetermined data value to the memory location associated with the first refreshable memory element. Each refreshable memory element may include a row of the dynamic random access memory device. The method may also include, after setting the indicator associated with the first refreshable memory element to the first value, detecting a read from the memory location and providing the predetermined data value in response. A memory controller or an operating system may detect the data value being written to the memory location associated with the first refreshable memory element. The indicators associated with the refreshable memory elements may be stored in static memory. Refreshing only the refreshable memory elements whose associated indicators have values different from the first value may include periodically refreshing the refreshable memory elements whose associated indicators have a value different from the first value, and not refreshing the refreshable memory elements whose associated indicators have the first value. The method may also include receiving a read request for the memory location associated with a first refreshable memory element, and providing the predetermined data value in response to the read request without performing a read operation from the memory location.

In a second general aspect, an article includes a tangible computer-readable data storage medium storing program code operable to cause one or more machines to perform operations, including associating, for each refreshable memory element of a dynamic random access memory device, an indicator with the refreshable memory element. The operations also include detecting a predetermined data value being written to a memory location associated with a first refreshable memory element, and setting the indicator associated with the first refreshable memory element to a first value. The operations further include refreshing only the refreshable memory elements of the dynamic random access memory device whose associated indicators have values different from the first value, wherein refreshing does not comprise refreshing the first refreshable memory element.

In various implementations, refreshing only the refreshable memory elements whose associated indicators have values different from the first value may include periodically refreshing the refreshable memory elements whose associated indicators have a value different from the first value, and not refreshing the refreshable memory elements whose associated indicators have the first value. The program code may be operable to cause the one or more machines to receive a read request for the memory location associated with a first refreshable memory element, and provide the predetermined data value in response to the read request without performing a read operation from the memory location.

In a third general aspect, a memory controller includes an interface module configured to interface with one or more dynamic random access memory devices, and a refresh controller. The refresh controller is configured to (i): associate, for each refreshable memory element of the one or more dynamic random access memory devices, an indicator with the refreshable memory element; (ii): detect a predetermined data value being written to a memory location associated with a first refreshable memory element, and set the indicator associated with the first refreshable memory element to a first value; and (iii): refresh only the refreshable memory elements of the one or more dynamic random access memory devices whose associated indicators have values different from the first value.

In various implementations, the predetermined data value may be zero. Each refreshable memory element may include a row of the one or more dynamic random access memory devices. The refresh controller may further be configured to, after setting the indicator associated with the first refreshable memory element to the first value, detect a read from the memory location and provide the predetermined data value in response. Refreshing only the refreshable memory elements whose associated indicators have values different from the first value may include periodically refreshing the refreshable memory elements whose associated indicators have a value different from the first value, and not refreshing the refreshable memory elements whose associated indicators have the first value. The refresh controller may be further configured to receive a read request for the memory location associated with a first refreshable memory element, and provide the predetermined data value in response to the read request without performing a read operation from the memory location.

The details of one or more embodiments are set forth in the accompanying drawings and the description below. Other features, objects, and advantages will be apparent from the description and drawings, and from the claims.

### DESCRIPTION OF DRAWINGS

FIG. 1 is a block diagram of an example computing device that can implement a power-conserving dynamic memory refresh technique.

FIG. 2 is a block diagram of an example memory controller.

FIG. 3 is a flow chart of example operations that can be performed by a memory controller to conserve power in implementations that use dynamic memory.

FIG. 4 is a flow chart of example operations that can be performed to service read requests to dynamic memory.

FIG. 5 shows an example of a generic computer device and a generic mobile computer device that may be used to implement the systems and methods described in this document.

Like reference symbols in the various drawings indicate like elements.

### DETAILED DESCRIPTION

Disclosed herein are methods, devices, and systems that can be used to reduce power consumption by recognizing opportunities to suspend memory refresh operations to applicable refreshable memory elements in devices or systems that use dynamic memory. The techniques may generally be transparent to an operating system or executing application of the device or system, for example, and memory performance may be substantially unchanged or minimally affected as compared to traditional systems that periodically refresh all dynamic memory locations. The power savings that may result from the techniques discussed herein may lead to increased battery life in battery-powered devices, according to some implementations.

The techniques discussed herein can be used to identify refreshable memory elements for which periodic refresh may be suspended, suppressed, discontinued, canceled, or omitted. In some implementations, identifying the refreshable memory element can include detecting a predetermined data value being written-to, or scheduled to be written-to, a memory location associated with the refreshable memory element. When the predetermined data value is detected being written-to a memory location associated with a refreshable memory element (or scheduled to be written to the memory location), a first value may be assigned to an indicator or flag that is associated with the refreshable memory element. Each refreshable memory element may be associated with an indicator, and only the refreshable memory elements whose associated indicators have values different from the first value may be refreshed, according to some implementations.

In this manner, a memory controller or controlling entity may selectively refresh only certain refreshable memory elements during a given refresh window or cycle, while refraining from refreshing other refreshable memory elements. The memory controller or controlling entity may refrain from refreshing those memory elements associated with a memory location to which the predetermined data value was written (or was scheduled to be written), and may thereby conserve refresh-cycle power.

In some implementations, when a read operation is later requested of the memory location, the memory controller or controlling entity may provide the predetermined data value to the requesting entity. The predetermined data value may be provided to the requesting entity without performing a read operation from the memory location of the dynamic memory device, as the contents at the memory location may be unreliable due to suspension of refresh operations to the memory element associated with the memory location. The predetermined data value may instead be provided, for example, from another memory location. In some implementations, the memory controller or controlling entity may check the indicator or flag associated with the memory element and memory location, and may provide the predetermined data value in response to the read request if the indicator has the first value. If the indicator does not have the first value, the memory contents at the memory location may be provided in response to the read request.

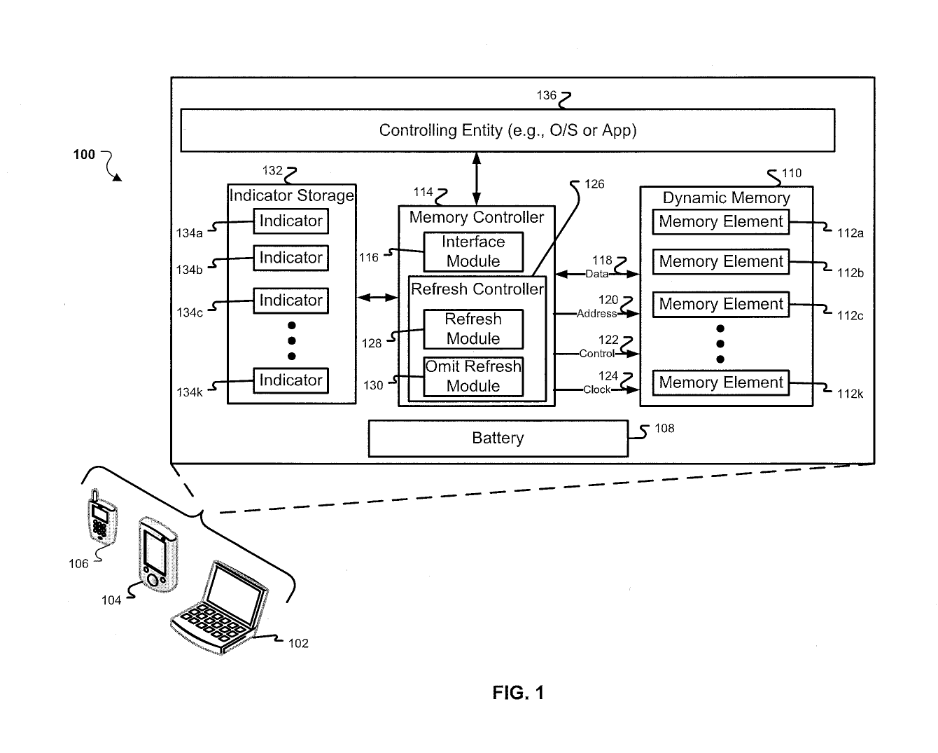

The power-saving techniques discussed herein do not rely on an additional communication channel between the memory controller and dynamic memory, for example. As will be described in more detail below with reference to FIG. 1, the memory controller may communicate with the dynamic memory using the standard data, address, and control busses.

FIG. 1 is a block diagram of an example computing device 100 that can implement power-conserving dynamic memory refresh techniques. The computing device 100 may represent, for example, a laptop computer 102, tablet computing device 104, smartphone 106, personal digital assistant (PDA), pager, navigation device, e-reading device, portable media player, or other type of device that uses dynamic memory. In various implementations, the computing device 100 may be battery-powered and include a battery 108 that supplies power to the various devices and circuits included within the computing device 100.

The device 100 includes dynamic memory 110, such as one or more dynamic random access memory (DRAM) devices. Examples of DRAM devices can include, without limitation, extended-data-out DRAM (EDO DRAM), synchronous DRAM (SDRAM), double-data-rate synchronous DRAM (DDR SDRAM), DDR2 SDRAM, DDR3 SDRAM, DDR4 SDRAM, video DRAM (VRAM), or other types of DRAM or dynamic memory. The dynamic memory 110 includes an array of refreshable memory elements 112a, 112b, 112c, . . . , 112k, each of which may be individually refreshed to preserve data values assigned to memory locations associated with the refreshable memory elements 112a, 112b, 112c, . . . , 112k.

In some implementations, each refreshable memory element may represent one row of the one or more dynamic memory devices 110. In some examples, a refreshable memory element (e.g., element 112a) may represent a row within a single dynamic memory device, and in some examples a refreshable memory element may represent a row across two or more dynamic memory devices (e.g., across two or more banks of the memory 110). Each refreshable memory element 112 may represent a portion of dynamic memory 110 that can be refreshed in a single refresh operation, for example.

In some implementations, the refreshable memory elements 112 may represent a portion of dynamic memory other than a row of memory. For example, the refreshable memory elements 112 may represent a portion of dynamic memory smaller than a row of memory, or a portion of dynamic memory larger than a row of memory. In some implementations, each refreshable memory element 112 may represent an addressable location having both a row address and a column address within the dynamic memory 110.

A memory controller 114 uses an interface module 116 to communicate with the dynamic memory 110. For example, the memory controller 114 can write one or more data values to one or more memory locations of the dynamic memory 110, and can read one or more data values from one or more memory locations of the dynamic memory 110. The memory controller 114 writes data to the memory 110 and reads data from the memory 110 over a bidirectional data bus 118. The memory controller 114 provides addresses for the memory locations to the memory 110 over an address bus 120. The memory controller provides control signals 122 to the memory 110 to control operations (e.g., read, write, refresh, or other memory operations) between the memory controller 114 and the memory 110. In implementations that use synchronous dynamic memory, the memory controller 114 may provide one or more clock signals 124 to the memory 110. In implementations that use asynchronous dynamic memory, the one or more clock signals 124 may be omitted. In some implementations, memory controller 114, or portions thereof, may be implemented within the dynamic memory device 110. In some implementations the memory controller 114, or portions thereof, may be implemented outside of the dynamic memory device 110.

The memory controller 114 includes a refresh controller 126 that can manage refresh operations for the dynamic memory 110 and provide refresh control signals to the dynamic memory 110. The refresh control signals may cause one or more refreshable memory elements (e.g., one or more of elements 112a, 112b, 112c, . . . , 112k) to be refreshed so that data values stored in memory locations associated with the memory elements 112 may be preserved. A refresh module 128 can manage a refresh window or period of time during which refreshable memory elements 112 should be refreshed so that data contents therein do not unduly degrade due to charge leakage. The refresh module 128 may provide, within each refresh window, refresh control signals to the dynamic memory 110. In various implementations, the refresh control signals provided to the dynamic memory 110 may specify which refreshable memory elements 112 of the dynamic memory 110 are to be refreshed.

In some implementations, the memory controller 114 can recognize opportunities to suspend memory refresh operations to applicable refreshable memory elements of the dynamic memory 110 so that power may be conserved. For example, an omit refresh module 130 can detect a predetermined data value being written-to a memory location associated with a refreshable memory element (e.g., element 112a) of the dynamic memory 110, and can identify the refreshable memory element 112a as appropriate for suspending refresh provisions thereto based on the detection. In some implementations, the omit refresh module 130 can detect a predetermined data value that is scheduled to be written-to a memory location associated with a refreshable memory element (e.g., element 112b) of the dynamic memory 110, and can identify the refreshable memory element 112b as appropriate for suspending refresh provisions thereto based on the detection, even if the data value is not actually written to the memory location of the dynamic memory.

The omit refresh module 130 can thus distinguish memory elements for which refresh operations may be suspended from those for which refresh operations may not be suspended based on a detection of the predetermined data value. In some examples, the memory controller 114 may write the predetermined data value to the memory location. In other examples, the memory controller 114 may not write the predetermined data value to the memory location, even though the value may have been scheduled to be written to the memory location.

Examples of the predetermined data value that can be detected to identify candidate elements for non-refresh can include the value “zero” (e.g., 0x0 in hexadecimal notation), or null data. Other examples of the predetermined data value can include an alternating pattern of zeros and ones (e.g., 0xAAAA or 0x5555), or other appropriate bit patterns (e.g., 0xAA55, 0x55AA, 0x3333, 0xCCCC, or others).

In some implementations, detection of the predetermined data value to identify a candidate memory element 112 may generally be made without knowledge of an underlying instruction (e.g., associated with an executing application or operating system operation) responsible for causing the predetermined data value to be written-to (or scheduled to be written-to) the dynamic memory 110. In particular, the detection may be based solely on the predetermined data value being written-to the dynamic memory 110 over the same data bus 118 by which data otherwise passes to/from the memory 110, without regard to additional information as to why such data value is being written to the memory 110, and without utilizing a separate communication channel to the memory 110, according to some implementations.

An array of indicators 132 includes individual indicators 134a, 134b, 134c, . . . , 134k. In some implementations, the memory controller 114 may uniquely associate an indicator 134 from the array of indicators 132 with a refreshable memory element 112 of the dynamic memory 110. For example, indicator 134a may be associated with memory element 112a; indicator 134b may be associated with memory element 112b; indicator 134c may be associated with memory element 112c; . . . , indicator 134k may be associated with memory element 112k. Each refreshable memory element 112 of the dynamic memory 110 may be associated with one of the indicators 134 in the array of indicators 132, for example.

In some implementations, each indicator 134 may comprise a digital storage location, such as one bit of storage that may take a value of “0” or “1,” for example. In other implementations, the indicators 134 may comprise an amount of storage larger than one bit. Examples of storage-size constructs that may be used to store each indicator 134 can include one bit, a nibble (e.g., 4 bits), a byte (e.g., 8 bits), a word (e.g., 16 bits), a long-word (e.g., 32 bits), a 64-bit construct, or other appropriate storage-size constructs.

The array of indicators 132 may be stored in static memory or in dynamic memory, or in volatile or non-volatile memory, according to various implementations. For example, the array of indicators 132 may be stored in cache memory, such as in an on-chip cache of a processor or in an off-chip cache (e.g., in SRAM), or in a register set of a processor. In some examples, the array of indicators 132 may be stored in dynamic memory 110. In some implementations, an indicator may be stored in the same memory device as the refreshable memory element with which it is associated. In other implementations, an indicator may be stored in a different device than the refreshable memory element with which it is associated. Each indicator 134 can be used to store a refresh status for the corresponding refreshable memory element 112.

The memory controller 114 may assign a value to an indicator 134 to indicate whether the corresponding refreshable memory element 112 should be refreshed or not. In some examples, the indicators may be assigned one of two values to indicate a status regarding refreshing. A first value may be assigned to an indicator 134 to indicate that the corresponding refreshable memory element 112 should not be refreshed while the indicator 134 has the first value. A second value may be assigned to the indicator 134 to indicate that the corresponding refreshable memory element 112 should be refreshed while the indicator 134 has the second value. In some examples, any value other than the first value (including, e.g., the second value or an indeterminate value) may indicate that the corresponding refreshable memory element should be refreshed.

After identifying a memory element for which refresh operations may be suspended (e.g., element 112a), for example, the omit refresh module 128 may set or assign the corresponding indicator (e.g., indicator 134a) to a first value (e.g., ‘1’). In some implementations, all of the indicators 134 or the array of indicators 132 may initially or nominally be set or assigned to a second value (e.g., ‘0’) to indicate that the corresponding memory element 112 should be refreshed. As memory elements 112 are identified for which refresh operations may be suspended, the memory controller 114 may set the corresponding indicator 134 to the first value (‘1’), for example. If a value other than the predetermined data value is written to a memory location of the dynamic memory 110, the memory controller may set or assign appropriate indicator the second value, or verify that the indicator is already assigned the second value. Values other than “1” and “0” may be used as first and second values, depending on the implementation.

In some implementations, the memory controller 114 may reference or determine the status of the indicators 134, and may refresh only those refreshable memory elements 112 associated with an indicator having a value different from the first value (e.g., the second value, other value, or an indeterminate value). The set of indicators 132 may be stored as a look-up table, for example, and prior to a refresh operation or series of refresh operations the memory controller 114 may access the look-up table to determine the status of the indicators. The controller 114 may then omit refreshing those memory elements associated with indicators having the first value, for example, and refresh all other memory elements. In various implementations, the refresh module 128 and the omit refresh module 130 may communicate so that only of subset of the total number of refreshable memory elements 112 of the dynamic memory 110 are refreshed within a given refresh window, as described above.

In some implementations, the controller or refresh logic may nominally be configured to periodically refresh all refreshable memory elements, but may include logic that causes refresh operations to be suspended (e.g., withheld or skipped) for those refreshable memory elements associated with an indicator having the first value. In some implementations, the refresh controller or refresh logic may refresh only those refreshable memory elements associated with an indicator that indicates the element should be refreshed (e.g., those indicators assigned the second value in this example).

The indicators may initially be assigned to indicate that refreshing should occur (e.g., by assigning the second value to the indicators), and when it is later determined that a particular memory element should not be refreshed, the corresponding indicator may be assigned accordingly (e.g., by assigning the first value to the indicator). In some cases, it may be determined that a group of memory elements (e.g., a block or page of memory) should not be refreshed, and the corresponding indicators may each be assigned to indicate that refreshing should not occur (e.g., by assigning the first value to the indicators). As described above, when any value other than the predetermined data value is written to a memory location, the memory controller 114 should set or assign a value different from the first value (e.g., the second value) to the corresponding indicator.

Despite refresh operations being withheld from selected refreshable memory elements, a controlling entity 136 (e.g., an operating system or executing application) may continue to utilize any and all memory locations of the dynamic memory 110 as it normally would in the absence of the power-conservation techniques discussed herein. For example, even though the memory contents of memory elements for which refresh has been suspended may become indeterminate due to charge leakage and lack of refresh, the memory controller 114 may service read requests to the corresponding memory locations by providing the predetermined value in response to the read request.

In some implementations, each time a read request is made of a memory location (e.g., by controlling entity 136), the memory controller 114 may check to see whether the corresponding indicator 134 is set to the first value. If the corresponding indicator is set to the first value, the memory controller 114 may provide the predetermined value to the controlling entity 136 in response to the read request without actually reading from the corresponding memory location. The predetermined value may be stored at a memory location (not shown in FIG. 1) within the memory controller 114, for example, or in another appropriate memory location. If the corresponding indicator 134 is not set to the first value, for example, the memory controller 114 may execute the read instruction from the dynamic memory 110 as it normally would.

The discussion above has generally focused on the memory controller 114 recognizing an opportunity for suspending refresh operations to particular refreshable memory elements and coordinating refresh actions accordingly. In some implementations, controlling entity 136, such as an operating system or an application, may alternatively recognize such opportunities. For example, the controlling entity 136 may identify that the predetermined data value will be written to memory, and may notify the memory controller 114 so that the omit refresh processing can occur. In some cases, the controlling entity 136 may interface with the array of indicators 132, as by setting the indicators to appropriate values and referencing the indicators to determine refresh applicability. In some implementations, the refresh controller may be included, in whole or in part, within the dynamic memory device 110.

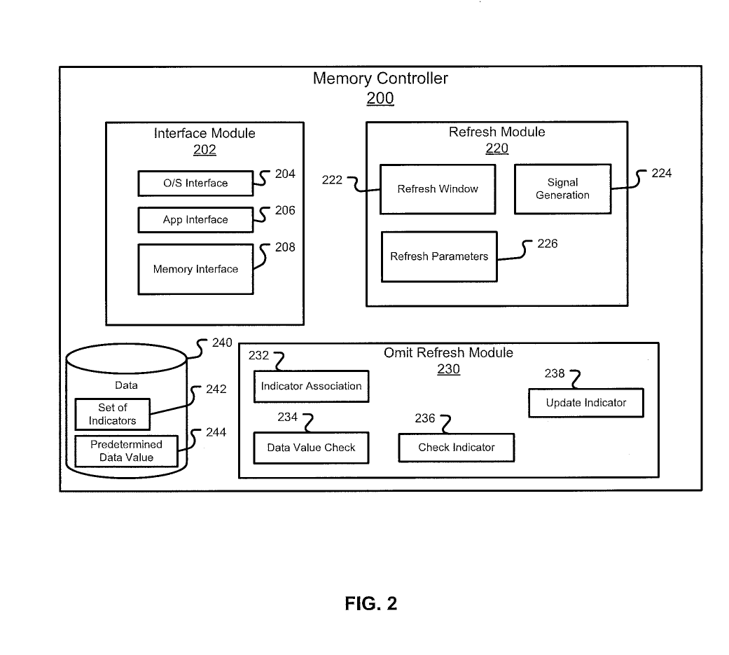

FIG. 2 is a block diagram of an example memory controller 200. Memory controller 200 may be included in a device or system that uses dynamic memory, and may reduce power consumption by recognizing opportunities to suspend memory refresh operations to applicable refreshable memory elements of the dynamic memory, according to some implementations. In some implementations, memory controller 200 may correspond to memory controller 114 of FIG. 1.

The memory controller 200 includes an interface module 202. The interface module 202 includes an operating system interface 204 that the memory controller 200 may use to interface with an operating system of the device. The interface module 202 includes one or more application interfaces 206 that the memory controller 200 may use to interface with one or more applications executing on device. The interface module 202 additionally includes a memory interface 208 that the memory controller 200 may use to interface with various types of memory included with the device. For example, the memory interface 208 may be used to interface with the dynamic memory 110 of the device, and optionally with other types of volatile or non-volatile memory of the device (e.g., disk, flash, DRAM, SRAM, the memory where the indicators are stored, removable memory, and the like).

The memory controller 200 includes a refresh module 220, which in some implementations may correspond to the refresh module 128 of FIG. 1. The refresh module 220 includes a refresh window component 222 that can manage the refresh window during which any refreshable memory elements 112 to be refreshed should be refreshed. The refresh window may be determined, for example, based on an amount of time that the cells of the dynamic memory may reliably hold their charges. A signal generation component 224 can generate refresh signals that can be supplied to the dynamic memory 110 to cause memory elements 112 to be refreshed. A refresh parameters component 226 can include refresh-related parameters, and can be used in providing the refresh functionality discussed herein.

The memory controller 200 also includes an omit refresh module 230, which in some implementations may correspond to the omit refresh module 130 of FIG. 1. The omit refresh module 230 includes an indicator association component 232 that can associate individual indicators of a set of indicators 242 with individual refreshable memory elements of the dynamic memory. As depicted in FIG. 2, the set of indicators 242 is shown stored in memory 240 of the memory controller 200, but in other implementations the set of indicators may be stored in any appropriate memory location.

A data value check component 234 can compare data values that are written-to dynamic memory or scheduled to be written to dynamic memory to a predetermined data value. In various implementations, the data value check component 234 may detect the data value upon the value's arrival at the memory controller from a controlling entity (e.g., entity 136 of FIG. 1). In some implementations, the data value check component 234 may detect the data value as it is being written to dynamic memory, such as over data bus 118 (see FIG. 1). In some implementations, value may be detected within a register (not shown) of the memory controller 200. In some implementations, the set of indicators 242 may correspond to the array of indicators 132 of FIG. 1.

A check indicator component 236 can determine the status of individual indicators from the set of indicators 242. For example, the check indicator component 236 may determine the status of each indicator of the set of indicators prior to or during a refresh cycle, and may communicate with the refresh module 220 so that refresh of appropriate memory elements may be skipped. In some implementations, the check indicator component 236 may indicate those refreshable memory elements whose associated indicators have the first value, for example, and the refresh module 220 may omit refreshing the corresponding memory elements of dynamic memory. In some implementations, the check indicator component 236 may indicate those refreshable memory elements whose associated indicators have the second value, for example, and the refresh module 220 may refresh the corresponding memory elements of dynamic memory. In some implementations, the check indicator component 236 may indicate those refreshable memory elements whose associated indicators have any value other than the first value, for example, and the refresh module 220 may refresh the corresponding memory elements of dynamic memory.

One or more predetermined data values 244 may also be stored in the data store 230, in some implementations. The data value check component 234 may compare data values being written to memory (or scheduled to be written to memory) to the predetermined data value 244, and if the comparison results in a match, an update indicator component 238 may set or assign the first value to the associated indicator in the set of indicators 242. If the comparison does not result in a match, the update indicator component 238 may set or assign the second value to the associated indicator in the set of indicators 242.

The predetermined data value 244 may also be provided in response to read requests from a memory location associated with a memory element to which refresh operations have been suspended. For example, for every read request corresponding to a memory location in dynamic memory, the check indicator component 236 may determine whether the corresponding indicator in the set of indicators 242 has the first value. As described previously, indicators storing the first value not only may indicate that refresh operations to the corresponding memory element may be suspended, leaving the memory contents potentially unreliable, but also may indicate that the most recent write to the corresponding memory location included the predetermined data value. This information may be provided to the interface module 202, so that the predetermined data value 244 may be provided in response to the read request, and so that the actual read from the memory location may be skipped or prevented.

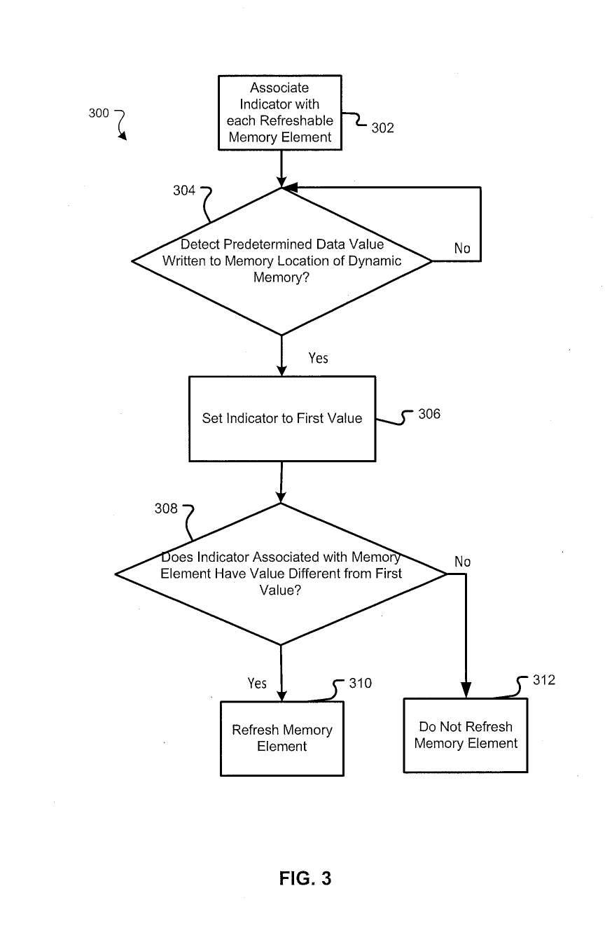

FIG. 3 is a flow chart 300 of example operations that can be performed by a memory controller to conserve power in implementations that use dynamic memory. In various implementations, the operations may be performed by a memory controller of a device that uses dynamic memory, for example.

At step 302, an indicator is associated with each refreshable memory element of dynamic memory of the device. The indicators may be stored as an array of indicators, where each indicator may be uniquely associated with a refreshable memory element (e.g., a row of dynamic memory) of one or more dynamic memory devices. The indicators may be stored in storage locations within the memory controller in some implementations, or may be stored outside of the memory controller. The indicators may be stored in static memory or in dynamic memory. The indicators may be stored in volatile memory or in non-volatile memory.

At step 304, if it is detected that a predetermined data value is being written to a memory location of the dynamic memory, where the memory location is associated with a memory element of the dynamic memory, the indicator associated with the memory element is set to a first value (306). In some examples, the predetermined data value may be zero, but any appropriate predetermined data value may be used.

At step 308, if an indicator associated with a refreshable memory element has a value different from the first value, the associated memory element is refreshed (310). If the indicator associated with the refreshable memory element has the first value, the associated memory element is not refreshed (312).

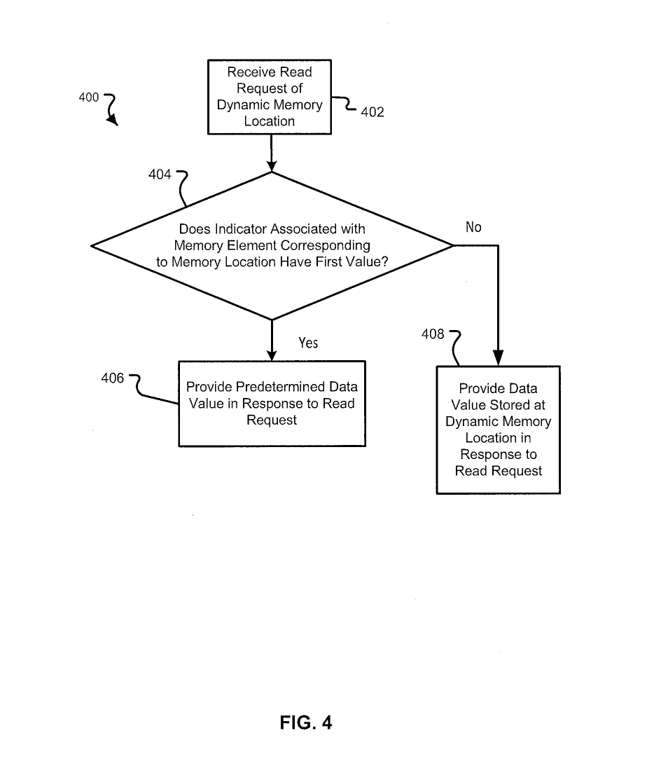

FIG. 4 is a flow chart 400 of example operations that can be performed by a memory controller to service read requests to dynamic memory. At step 402, a read request of a dynamic memory location is received. The read request may be received at a memory controlled from a controlling entity, such as an operating system or an application executing on the device, for example. If an indicator associated with the refreshable memory element that corresponds to the dynamic memory location has the first value at step 404, a predetermined data value is provided in response to the read request (406). The predetermined data value may be provided from a memory location different from the requested dynamic memory location, for example, and the read from the dynamic memory location me be omitted. If the indicator associated with the refreshable memory element that corresponds to the dynamic memory location does not have the first value at step 404, a data value stored at the dynamic memory location is provided in response to the read request (408).

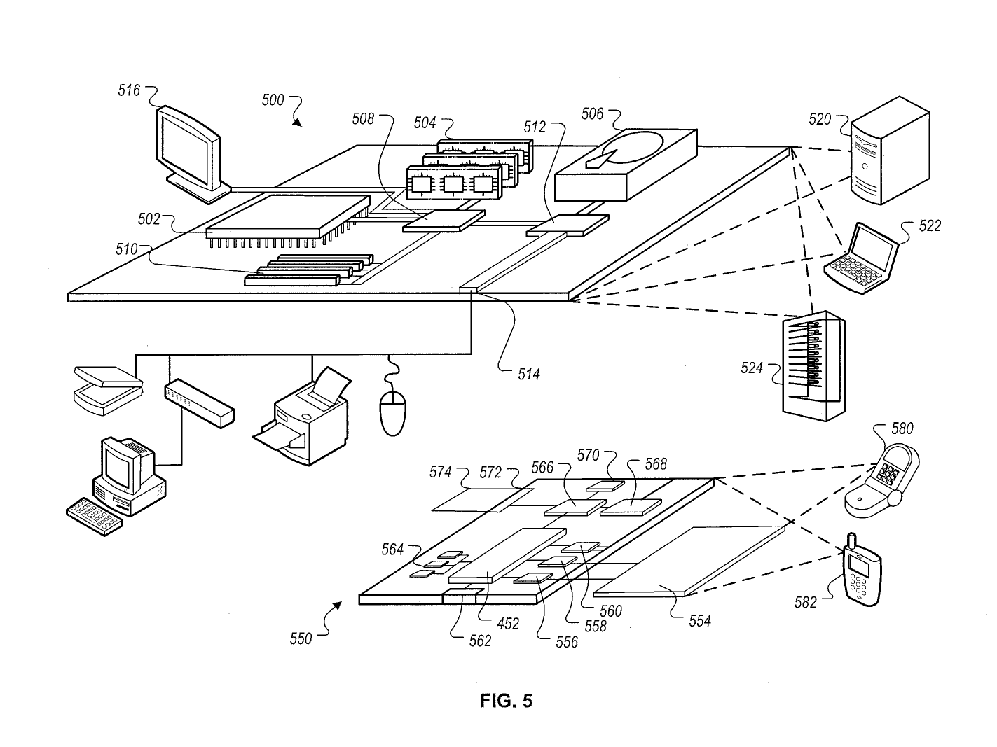

FIG. 5 shows an example of a generic computer device 500 and a generic mobile computer device 550 that may be used to implement the systems and methods described in this document. Computing device 500 is intended to represent various forms of digital computers, such as laptops, desktops, workstations, servers, blade servers, mainframes, and other appropriate computers. Computing device 550 is intended to represent various forms of mobile devices, such as personal digital assistants, cellular telephones, smartphones, tablet computing devices, and other similar computing devices. The components shown here, their connections and relationships, and their functions, are meant to be exemplary only, and are not meant to limit implementations of the systems, methods, devices or techniques described and/or claimed in this document.

Computing device 500 includes a processor 502, memory 504, a storage device 506, a high-speed interface 508 connecting to memory 504 and high-speed expansion ports 510, and a low speed interface 512 connecting to low speed bus 514 and storage device 506. Each of the components 502, 504, 506, 508, 510, and 512 are interconnected using various busses, and may be mounted on a common motherboard or in other manners as appropriate. The processor 502 can process instructions for execution within the computing device 500, including instructions stored in the memory 504 or on the storage device 506 to display graphical information for a GUI on an external input/output device, such as display 516 coupled to high speed interface 508. In other implementations, multiple processors and/or multiple buses may be used, as appropriate, along with multiple memories and types of memory. Also, multiple computing devices 500 may be connected, with each device providing portions of the necessary operations (e.g., as a server bank, a group of blade servers, or a multi-processor system).

The memory 504 stores information within the computing device 500. In one implementation, the memory 504 is a computer-readable medium. In one implementation, the memory 504 is a volatile memory unit or units. In another implementation, the memory 504 is a non-volatile memory unit or units.

The storage device 506 is capable of providing mass storage for the computing device 500. In one implementation, the storage device 506 is a computer-readable medium. In various different implementations, the storage device 506 may be a floppy disk device, a hard disk device, an optical disk device, a tape device, a flash memory or other similar solid-state memory device, or an array of devices, including devices in a storage area network or other configurations. In one implementation, a computer program product is tangibly embodied in an information carrier. The computer program product contains instructions that, when executed, perform one or more methods, such as those described above. The information carrier is a computer- or machine-readable medium, such as the memory 504, the storage device 506, memory on processor 502, or a propagated signal.

The high speed controller 508 manages bandwidth-intensive operations for the computing device 500, while the low speed controller 512 manages lower-bandwidth-intensive operations. Such allocation of duties is exemplary only. In one implementation, the high-speed controller 508 is coupled to memory 504, display 516 (e.g., through a graphics processor or accelerator), and to high-speed expansion ports 510, which may accept various expansion cards (not shown). In the implementation, low-speed controller 512 is coupled to storage device 506 and low-speed expansion port 514. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 500 may be implemented in a number of different forms, as shown in the figure. For example, it may be implemented as a standard server 520, or multiple times in a group of such servers. It may also be implemented as part of a rack server system 524. In addition, it may be implemented in a personal computer such as a laptop computer 522. Alternatively, components from computing device 500 may be combined with other components in a mobile device (not shown), such as device 550. Each of such devices may contain one or more of computing device 500, 550, and an entire system may be made up of multiple computing devices 500, 550 communicating with each other.

Computing device 550 includes a processor 552, memory 564, an input/output device such as a display 554, a communication interface 566, and a transceiver 568, among other components. The device 550 may also be provided with a storage device, such as a microdrive or other device, to provide additional storage. Each of the components 552, 564, 554, 566, and 568, are interconnected using various buses, and several of the components may be mounted on a common motherboard or in other manners as appropriate.

The processor 552 can process instructions for execution within the computing device 550, including instructions stored in the memory 564. The processor may also include separate analog and digital processors. The processor may provide, for example, for coordination of the other components of the device 550, such as control of user interfaces, applications run by device 550, and wireless communication by the device 550.

Processor 552 may communicate with a user through control interface 558 and display interface 556 coupled to the display 554. The display 554 may be, for example, a TFT LCD display or an OLED display, or other appropriate display technology. The display interface 556 may comprise appropriate circuitry for driving the display 554 to present graphical and other information to a user. The control interface 558 may receive commands from a user and convert them for submission to the processor 552. In addition, an external interface 562 may be provided in communication with processor 552, so as to enable near-area communication of device 550 with other devices. External interface 562 may provide, for example, for wired communication (e.g., via a docking procedure) or for wireless communication (e.g., via Bluetooth or other such technologies).

The memory 564 stores information within the computing device 550. In one implementation, the memory 564 is a computer-readable medium. In one implementation, the memory 564 is a volatile memory unit or units. In another implementation, the memory 564 is a non-volatile memory unit or units. Expansion memory 574 may also be provided and connected to device 550 through expansion interface 572, which may include, for example, a SIMM card interface. Such expansion memory 574 may provide extra storage space for device 550, or may also store applications or other information for device 550. Specifically, expansion memory 574 may include instructions to carry out or supplement the processes described above, and may also include secure information. Thus, for example, expansion memory 574 may be provided as a security module for device 550, and may be programmed with instructions that permit secure use of device 550. In addition, secure applications may be provided via the SIMM cards, along with additional information, such as placing identifying information on the SIMM card in a non-hackable manner.

The memory may include, for example, flash memory and/or MRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 564, expansion memory 574, memory on processor 552, or a propagated signal.

In some implementations, device 550 may communicate wirelessly through communication interface 566, which may include digital signal processing circuitry as appropriate. Communication interface 566 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 568. In addition, short-range communication may occur, such as using a Bluetooth, WiFi, or other such transceiver (not shown). In addition, GPS receiver module 570 may provide additional wireless data to device 550, which may be used as appropriate by applications running on device 550.

Device 550 may also communicate audibly using audio codec 560, which may receive spoken information from a user and convert it to usable digital information. Audio codec 560 may likewise generate audible sound for a user, such as through a speaker, e.g., in a handset of device 550. Such sound may include sound from voice telephone calls, may include recorded sound (e.g., voice messages or music files) and may also include sound generated by applications operating on device 550.

The computing device 550 may be implemented in a number of different forms, as shown in the figure. For example, it may be implemented as a cellular telephone 580. It may also be implemented as part of a smartphone 582, personal digital assistant, tablet computing device, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback), and input from the user can be received in any form, including acoustic, speech, or tactile input.

A number of embodiments have been described. Nevertheless, it will be understood that various modifications may be made. Although several applications of the systems and methods have been described, it should be recognized that numerous other applications are contemplated. Accordingly, other embodiments are within the scope of the following claims.

1. A method of refreshing dynamic memory, comprising:
associating, for each refreshable portion of multiple refreshable portions of a first memory device, an indicator with the respective refreshable portion;
determining that a first refreshable portion of the multiple refreshable portions is populated with a written predetermined data value;
in response to determining that the first refreshable portion is populated with the written predetermined data value, setting the indicator associated with the first refreshable portion to a first value; and
determining to bypass performing refresh operations on one or more refreshable portions, including the first refreshable portion, that are associated with indicators having the first value.

2. The method of claim 1, wherein the written predetermined data value is zero.

3. The method of claim 1, wherein an operating system initiates the writing of the written predetermined data value to the first refreshable portion.

4. The method of claim 1, wherein an application initiates the writing of the written predetermined data value to first refreshable portion.

5. The method of claim 1, wherein each refreshable portion comprises a row of a dynamic random access memory device.

6. The method of claim 1, further comprising, after setting the indicator associated with the first refreshable portion to the first value, detecting a read for a memory location associated with the first refreshable portion; and providing the written predetermined data value in response.

7.-8. (canceled)

9. The method of claim 1, wherein the indicators associated with the refreshable portions are stored in a static memory.

10. The method of claim 1, comprising periodically refreshing the refreshable portions whose associated indicators have a value different from the first value.

11. The method of claim 1, further comprising:
receiving a read request for a the first refreshable portion;
determining that the indicator associated with the first refreshable portion is set to the first value; and
in response to receiving the read request and determining that the indicator associated with the first refreshable portion is set to the first value, providing the written predetermined data value without performing a read operation on the first refreshable portion.

12. An article comprising a non-transitory computer-readable data storage medium storing program code operable to cause one or more machines to perform operations, the operations comprising:
associating, for each refreshable portion of multiple refreshable portions of a first memory device, an indicator with the respective refreshable portion;
determining that a first refreshable portion of the multiple refreshable portions is populated with a written predetermined data value;
in response to determining that the first refreshable portion is populated with the written predetermined data value, setting the indicator associated with the first refreshable portion to a first value; and
determining to bypass performing refresh operations on one or more refreshable portions, including the first refreshable portion, that are associated with indicators having the first value.

13. The article of claim 12, wherein the operations further comprise periodically refreshing the refreshable portions whose associated indicators have a value different from the first value.

14. The article of claim 12, wherein the operations further comprise
receive a read request for a the first refreshable portion;
determine that the indicator associated with the first refreshable portion is set to the first value; and
in response to receiving the read request and determining that the indicator associated with the first refreshable portion is set to the first value, provide the written predetermined data value without performing a read operation on the first refreshable portion.

15. A memory controller, comprising:
an interface module configured to interface with one or more memory devices; and
a refresh controller configured to:
(i): associate, for each refreshable portion of multiple refreshable portions of a first memory device, an indicator with the respective refreshable portion;
(ii): determine that a first refreshable portion of the multiple refreshable portions is populated with a written predetermined data value;
(iii): in response to determining that the first refreshable portion is populated with the written predetermined data value, set the indicator associated with the first refreshable portion to a first value; and
(iv): determine to bypass performing refresh operations on one or more refreshable portions, including the first refreshable portion, that are associated with indicators having the first value.

16. The memory controller of claim 15, wherein the written predetermined data value is zero.

17. The memory controller of claim 15, wherein each refreshable portion comprises a row of the one or more memory devices.

18. The memory controller of claim 15, wherein the refresh controller is further configured to, after setting the indicator associated with the first refreshable portion to the first value, detect a read for a memory location associated with the first refreshable portion; and provide the written predetermined data value in response.

19. The memory controller of claim 15, wherein the refresh controller is configured to: periodically refresh the refreshable portions whose associated indicators have a value different from the first value.

20. The memory controller of claim 15, wherein the refresh controller is further configured to:
receiving a read request for a memory location associated with the first refreshable portion;
determining that the indicator associated with the first refreshable portion is set to the first value; and
in response to receiving the read request and determining that the indicator associated with the first refreshable portion is set to the first value, providing the written predetermined data value without performing a read operation on the first refreshable portion.

21. The method of claim 1, wherein the indicators associated with the multiple refreshable portions are stored in a second, different, memory device.

22. The method of claim 1, wherein each refreshable portion comprises a page of a dynamic random access memory device.
